(19) United States
(12) Patent Application Publication
(10) Pub. No.: US 2026/0229415 A1
(43) Pub. Date: Aug. 6, 2026

(54) CAPACITOR

(71) Applicant: ELSPES Inc., Daejeon (KR)

(72) Inventors: Ji Hoon CHA, Hwaseong-si (KR); Ui Hwan KIM, Hwaseong-si (KR); Seunggu LIM, Hwaseong-si (KR); Tae Dong KIM, Hwaseong-si (KR); Yeong Lyeol PARK, Yongin-si (KR); Dong Ki LEE, Hwaseong-si (KR); Hee Il CHAE, Hwaseong-si (KR); Won Soo CHOI, Seongnam-si (KR)

(21) Appl. No.: 19/442,496

(22) Filed: Jan. 7, 2026

(30) Foreign Application Priority Data
Feb. 6, 2025 (KR) 10-2025-0015379

(51) Int. Cl. H01G 4/38; H01G 4/30; H10D 1/68; H10D 84/00

(52) U.S. Cl. CPC H01G 4/38; H01G 4/30; H10D 1/714; H10D 1/716; H10D 84/212

(57) ABSTRACT

The present disclosure relates to a capacitor. A capacitor according to an embodiment of the present disclosure includes a plurality of first cells, wherein each of the plurality of first cells includes, a first trench array including a plurality of first trenches formed in a second direction on a substrate, a second trench array including a plurality of second trenches formed in a first direction on the substrate, a third trench array including a plurality of third trenches formed in the first direction on the substrate, a fourth trench array including a plurality of fourth trenches formed in the second direction on the substrate, and a capacitor layer including at least two electrode layers and at least one dielectric layer, wherein each of the plurality of first trenches and each of the plurality of fourth trenches are arranged in the first direction, each of the plurality of second trenches and each of the plurality of third trenches are arranged in the second direction, each of the plurality of first trenches to the plurality of fourth trenches includes a first empty area configured to separate each of the plurality of first trenches to the plurality of fourth trenches at a first ratio, the first trench array is disposed adjacent to the second trench array in the first direction and disposed adjacent to the third trench array in the second direction, the fourth trench array is disposed adjacent to the third trench array in the first direction and disposed adjacent to the second trench array in the second direction, and the capacitor layer is disposed on the substrate along the plurality of first trenches to the plurality of fourth trenches.

### CROSS-REFERENCE TO RELATED APPLICATION

This application claims priority to and the benefit of Korean Patent Application No. 2025-0015379, filed on Feb. 6, 2025, the disclosure of which is incorporated herein by reference in its entirety.

### BACKGROUND

### 1. Field of the Invention

The present disclosure relates to a capacitor, and more particularly, to a capacitor formed along a trench disposed in a substrate.

### 2. Discussion of Related Art

Capacitors are passive elements that store electrical energy in the form of electric charges. These capacitors may be passive elements that are connected to electrical circuits and driven or may also be designed in the form of chips and electrically connected to complex circuits.

As these chip capacitors are increasingly used in various electronic devices, there is an increasing need for high-performance system-on-chip (SOC) capacitors.

These chip capacitors may be designed in various forms according to the needs thereof. In particular, with the miniaturization of electronic devices, a design structure of capacitors has come to require a structure in which an increased number of capacitors are disposed on the same substrate area. In particular, recent capacitors are required to have higher capacitance within a specific area of a substrate. From this design perspective, a capacitor is formed in a metal-insulator-metal-insulator-metal . . . (MIMIM . . . ) structure on a plurality of deep trenches formed in an area of a substrate, thereby providing higher capacitance in a smaller area of the substrate.

However, such an increase in integration density of capacitors allows more electric charges to be stored in a smaller area but has a problem of causing side effects such as an increase in leakage current and a degradation in equivalent series inductance (ESL) and equivalent series resistance (ESR) characteristics.

Moreover, a design structure of capacitors is formed in a simple structure to improve the integration density of capacitors. However, a trench capacitor manufactured according to the above-described design structure has a structure that is vulnerable to external forces due to a simple arrangement structure of a pattern thereof. Thus, there is a problem that a chip capacitor may be easily damaged by physical forces generated during circuit mounting or other external forces directly applied to the chip.

Therefore, as an invention to solve the above-described problems, a capacitor according to the present disclosure is disclosed.

Meanwhile, the information in the background art described above was obtained by the inventors for the purpose of developing the present disclosure or was obtained during the process of developing the present disclosure. As such, it is to be appreciated that this information did not necessarily belong to the public domain before the patent filing date of the present disclosure.

### RELATED ART DOCUMENTS

### Patent Documents

(Patent Document 1) U.S. Patent Publication No. 2022-0393038 (Dec. 18, 2022)

### SUMMARY OF THE INVENTION

The present disclosure is directed to providing a capacitor including a pattern structure capable of withstanding external forces or deformation by diversifying a pattern structure of trenches formed in a substrate of a capacitor.

The present disclosure is also directed to providing a capacitor including a design structure that addresses an increase in leakage current and a degradation in electrical characteristics of a capacitor caused by an increase in integration density of capacitors disposed on a plurality of trenches in a substrate.

The present disclosure is also directed to providing a capacitor including a design structure that reduces process defects caused by process errors such as etching or deposition non-uniformity that may occur during a capacitor process due to an increase in integration density of capacitors. The present disclosure is also directed to securing a margin in a process of manufacturing a chip capacitor using such a capacitor.

The objects of the present disclosure are not limited to those described above, and other objects that are not described may become apparent to those of ordinary skill in the art based on the following descriptions.

According to an aspect of the present invention, there is provided a capacitor including a plurality of first cells, wherein each of the plurality of first cells includes, a first trench array including a plurality of first trenches formed in a second direction on a substrate, a second trench array including a plurality of second trenches formed in a first direction on the substrate, a third trench array including a plurality of third trenches formed in the first direction on the substrate, a fourth trench array including a plurality of fourth trenches formed in the second direction on the substrate, and a capacitor layer including at least two electrode layers and at least one dielectric layer, wherein each of the plurality of first trenches and each of the plurality of fourth trenches are arranged in the first direction, each of the plurality of second trenches and each of the plurality of third trenches are arranged in the second direction, each of the plurality of first trenches to the plurality of fourth trenches includes a first empty area configured to separate each of the plurality of first trenches to the plurality of fourth trenches at a first ratio, the first trench array is disposed adjacent to the second trench array in the first direction and disposed adjacent to the third trench array in the second direction, the fourth trench array is disposed adjacent to the third trench array in the first direction and disposed adjacent to the second trench array in the second direction, and the capacitor layer is disposed on the substrate along the plurality of first trenches to the plurality of fourth trenches.

The capacitor may further include a plurality of second cells, wherein each of the plurality of second cells includes a fifth trench array including a plurality of fifth trenches formed in the second direction on the substrate, a sixth trench array including a plurality of sixth trenches formed in the first direction on the substrate, a seventh trench array including a plurality of seventh trenches formed in the first direction on the substrate, an eighth trench array including a plurality of eighth trenches formed in the second direction on the substrate, and the capacitor layer, wherein each of the plurality of fifth trenches and each of the plurality of eighth trenches are arranged in the first direction, each of the plurality of sixth trenches and each of the plurality of seventh trenches are arranged in the second direction, each of the plurality of fifth trenches to the plurality of eighth trenches includes a second empty area configured to separate each of the plurality of fifth trenches to the plurality of eighth trenches at a second ratio, the fifth trench array is disposed adjacent to the sixth trench array in the first direction and disposed adjacent to the seventh trench array in the second direction, the ei ghth trench array is disposed adjacent to the seventh trench array in the first direction and disposed adjacent to the sixth trench array in the second direction, and the capacitor layer is disposed on the substrate along the fifth to eighth trenches.

The first ratio may be a ratio that is complementary to the second ratio.

In the capacitor, the number of the plurality of first trenches may be the same as the number of the plurality of fifth trenches, the number of the plurality of second trenches may be the same as the number of the plurality of sixth trenches, the number of the plurality of third trenches may be the same as the number of the plurality of seventh trenches, and the number of the plurality of fourth trenches may be the same as the number of the plurality of eighth trenches.

In each of the plurality of first cells, the number of the plurality of first trenches may be the same as the number of the plurality of fourth trenches, the number of the plurality of second trenches may be the same as the number of the plurality of third trenches, and the number of the plurality of first trenches may be different from the number of the plurality of second trenches.

In each of the plurality of first cells, the numbers of the plurality of first trenches to the plurality of fourth trenches may be the same.

In each of the plurality of first cells, the number of the plurality of first trenches may be the same as the number of the plurality of second trenches, the number of the plurality of third trenches may be the same as the number of the plurality of fourth trenches, and the number of the plurality of first trenches may be different from the number of the plurality of third trenches.

The capacitor may include at least two sets of the plurality of first cells and at least two sets of the plurality of second cells.

The plurality of first cells and the plurality of second cells may be alternately disposed adjacent to each other in the first direction and the second direction.

The plurality of first trenches and the plurality of fifth trenches may be disposed such that a first extension line in the first direction passing through a center of a first empty area formed in the plurality of first trenches is offset from a second extension line in the first direction passing through a center of a second empty area formed in the plurality of fifth trenches, the plurality of second trenches and the plurality of sixth trenches may be disposed such that a third extension line in the second direction passing through a center of the first empty area formed in the plurality of second trenches is offset from a fourth extension line in the second direction passing through a center of the second empty area formed in the plurality of sixth trenches, the plurality of third trenches and the plurality of seventh trenches may be disposed such that a fifth extension line in the second direction passing through a center of the first empty area formed in the plurality of third trenches is offset from a sixth extension line in the second direction passing through a center of the second empty area formed in the plurality of seventh trenches, and the plurality of fourth trenches and the plurality of eighth trenches may be disposed such that a seventh extension line in the first direction passing through a center of the first empty area formed in the plurality of fourth trenches is offset from an eighth extension line in the first direction passing through a center of the second empty area formed in the plurality of eighth trenches.

The capacitor may include a first support bar area corresponding to an area in which the first cell and the second cell are spaced apart from each other in the second direction, a second support bar area corresponding to an area in which the first trench array and the third trench array, the second trench array and the fourth trench array, the fifth trench array and the seventh trench array, and the sixth trench array and the eighth trench array are spaced apart from each other, a third support bar area corresponding to an area in which the first cell and the second cell are spaced apart from each other in the first direction, a fourth support bar area corresponding to an area in which the first trench array and the second trench array, the third trench array and the fourth trench array, the fifth trench array and the sixth trench array, and the seventh trench array and the eighth trench array are spaced apart from each other, and a fifth support bar area corresponding to the first empty area and the second empty area.

The capacitor may further include a plurality of metal contacts formed at points at which a plurality of first virtual center lines intersect a plurality of second virtual center lines, wherein the plurality of first virtual center lines pass through centers between the plurality of trenches disposed adjacent to each other and extend in an extending direction of each of the plurality of trenches in each of the first to eighth trench arrays, the plurality of second virtual center lines pass through a center of each of the first to fifth support bar areas and extend in an extending direction of each of the first to fifth support bar areas, and the plurality of metal contacts are formed in the first to fifth support bar areas along the plurality of second virtual center lines.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a plan view of a capacitor according to one embodiment of the present disclosure;

FIG. 2 is an enlarged view of portion II of FIG. 1;

FIG. 3 is an enlarged view of portion III of FIG. 1;

FIG. 4 is a plan view of the capacitor illustrating an extension line passing through the center of an empty area of the capacitor according to one embodiment of the present disclosure;

FIG. 5 is a partial plan view of the capacitor illustrating a plurality of metal contacts according to one embodiment of the present disclosure;

FIG. 6 is a plan view of the capacitor illustrating the plurality of metal contacts according to one embodiment of the present disclosure;

FIG. 7 is a cross-sectional view along line VII-VII′ of FIG. 6;

FIG. 8 is an enlarged view of portion VIII of FIG. 7;

FIG. 9 is an enlarged view of portion IX of FIG. 7;

FIG. 10 is a cross-sectional view along line X-X′ of FIG. 6;

FIG. 11 is an enlarged view of portion XI of FIG. 10;

FIG. 12 is an enlarged view of portion XII of FIG. 10;

FIG. 13 is an enlarged view of portion XIII of FIG. 10;

FIG. 14 is a plan view of one cell of a capacitor according to another embodiment of the present disclosure; and

FIG. 15 is a plan view of one cell of a capacitor according to still another embodiment of the present disclosure.

### DETAILED DESCRIPTION OF EXEMPLARY EMBODIMENTS

The advantages and features of the present disclosure and methods of accomplishing the same will become apparent from the following description of embodiments in detail, taken in conjunction with the accompanying drawings. However, the present disclosure is not limited to the embodiments disclosed herein but will be implemented in various forms. The embodiments are provided so that the present disclosure is completely disclosed, and a person of ordinary skilled in the art can fully understand the scope of the present disclosure. Therefore, the present disclosure will be defined only by the scope of the appended claims.

A shape, a size, a ratio, an angle, and a number disclosed in the drawings for describing embodiments of the present disclosure are merely an example, and thus, the present disclosure is not limited to the illustrated details. In addition, in describing the present disclosure, when it is determined that the specific description of the known related art unnecessarily obscures the gist of the present disclosure, the detailed description thereof will be omitted. Terms such as “including,” “having,” and “consist of” used herein are generally intended to allow other components to be added unless the terms are used with the term “only.” Any references to a singular form may include a plural form unless expressly stated otherwise.

Components are interpreted to include an ordinary error range even when not expressly stated.

Although the terms “first,” “second,” and the like are used to describe various components, these components are not limited by these terms. These terms are merely used to distinguish one component from another. Therefore, a first component to be described below may be a second component in a technical concept of the present disclosure.

Unless otherwise specified, like reference numerals refer to like elements throughout the specification.

The features of various embodiments of the present disclosure can be partially or entirely adhered to or combined with each other and can be interlocked and operated in technically various ways as understood by those skilled in the art, and the embodiments can be carried out independently of or in association with each other.

Terms used in the present specification below mean commonly used terms, but may be terms defined by the present applicant to convey a special meaning or clarify the meaning of the terms.

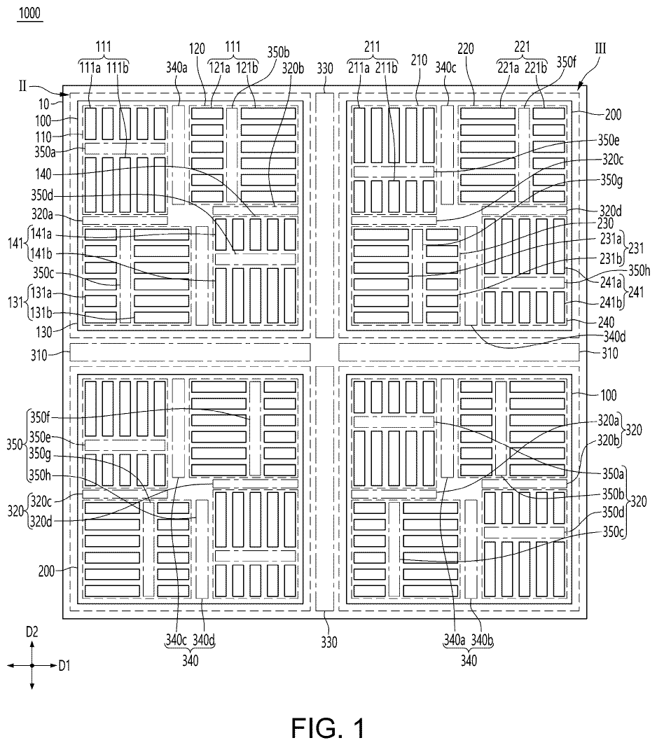

In the present specification, capacitors having various trench pattern structures will be described with reference to FIGS. 1 to 10. First, a capacitor 1000 according to one embodiment of the present disclosure will be described with reference to FIG. 1.

FIG. 1 is a plan view of the capacitor 1000 according to one embodiment of the present disclosure.

Referring to FIG. 1, the capacitor 1000 according to one embodiment of the present disclosure includes at least two sets of a plurality of first cells 100, at least two sets of a plurality of second cells 200, and a support bar area 300. Here, each of the first cell 100 and the second cell 200 may be a unit structure forming the capacitor 1000.

Each set of the plurality of first cells 100 includes first to fourth trench arrays 110 to 140. In addition, each set of the plurality of second cells 200 includes fifth to eighth trench arrays 210 to 240.

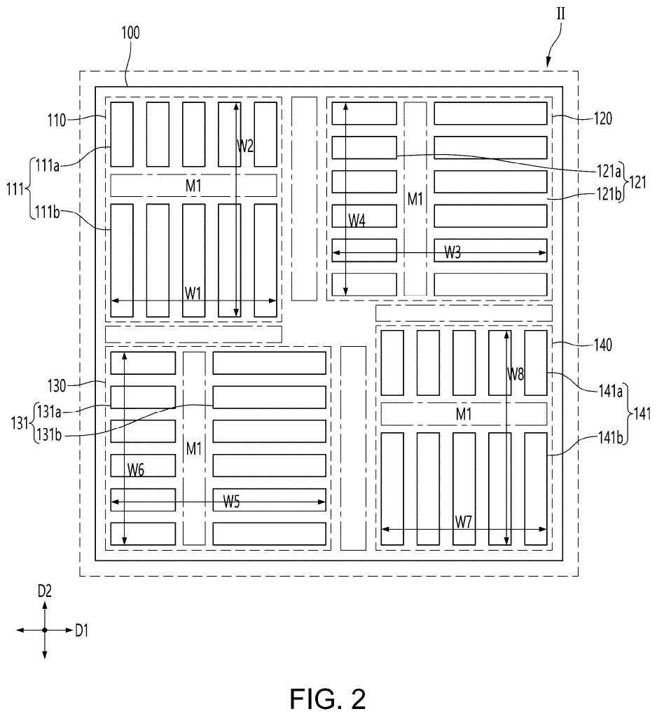

The first to fourth trench arrays 110 to 140 include a plurality of first trenches 111 to a plurality of fourth trenches 141 formed in a substrate 10, respectively. The detailed arrangement structure of the plurality of first trenches 111 to the plurality of fourth trenches 141 will be described below with reference to FIG. 2.

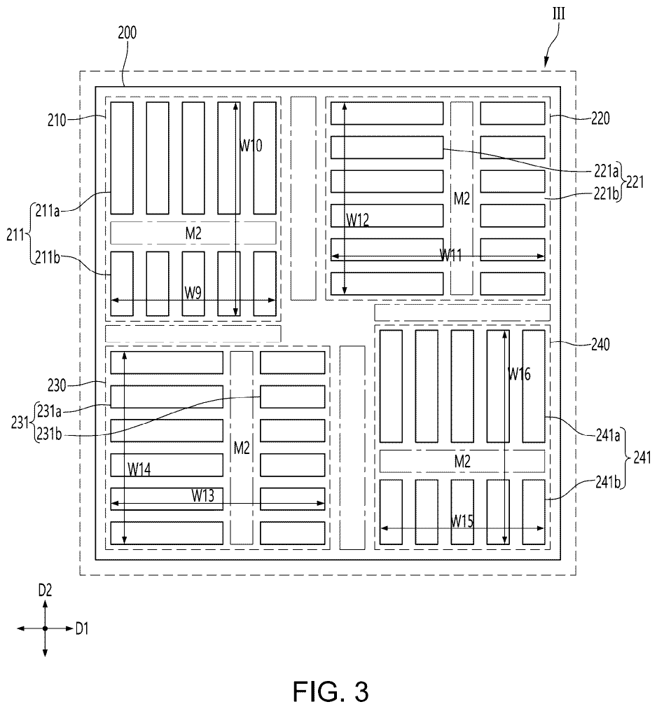

The fifth to eighth trench arrays 210 to 240 include a plurality of fifth trenches 211 to a plurality of eighth trenches 241 formed in the substrate 10, respectively. The detailed arrangement structure of the plurality of fifth trenches 211 to the plurality of eighth trenches 241 will be described below with reference to FIG. 3.

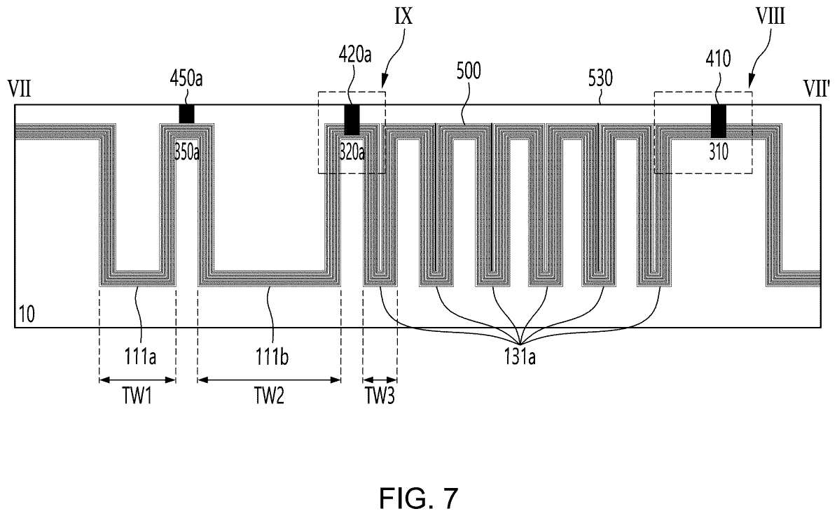

A capacitor is disposed in each of the plurality of first trenches 111 to the plurality of fourth trenches 141 and each of the plurality of fifth trenches 211 to the plurality of eighth trenches 241. The capacitor may include a plurality of layers. Accordingly, the capacitor is formed in a layered structure, and in the present specification, the capacitor disposed in each of the trenches are referred to as a capacitor layer to be distinguished from the entire capacitor. The capacitor layer will be described in detail below with reference to FIGS. 7 to 13.

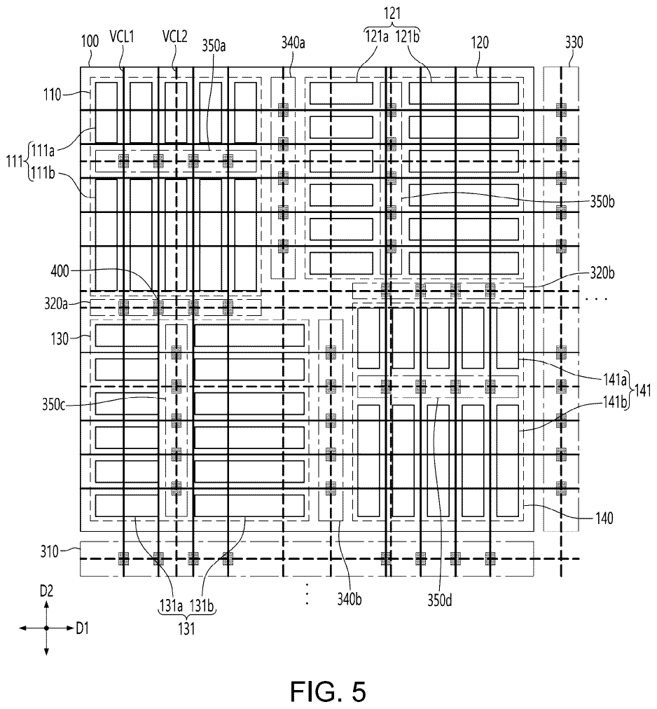

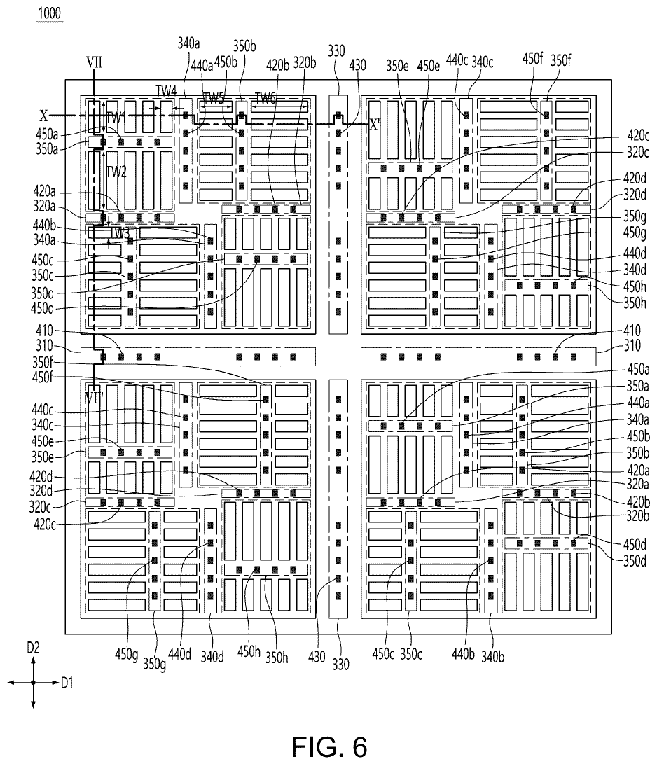

Referring to FIG. 1, the support bar area 300 includes first to fifth support bar areas 310 to 350. The first to fifth support bar areas 310 to 350 may be empty areas in which a plurality of trenches 111 to 141 and 211 to 241 are not disposed in the substrate 10 according to the arrangement structure of the plurality of trenches 111 to 141 and 211 to 241 disposed in the substrate 10. The first to fifth support bar areas 310 to 350 will be described in detail below with reference to FIGS. 5 and 6.

In the present specification, the arrangement structure of the plurality of first trenches 111 to the plurality of fourth trenches 141 of the capacitor 1000 according to one embodiment of the present disclosure will be described in detail with reference to FIGS. 1 and 2. Here, FIG. 2 is an enlarged view of portion II of FIG. 1.

Referring to FIGS. 1 and 2, each set of the first cells 100 includes one first trench array 110 to one fourth trench array 140. The first trench array 110 may be disposed adjacent to the second trench array 120 in a first direction D1. In addition, the first trench array 110 may be disposed adjacent to the third trench array 130 in a second direction D2 perpendicular to the first direction D1. In addition, the fourth trench array 140 may be disposed adjacent to the third trench array 130 in the first direction D1. In addition, the fourth trench array 140 may be disposed adjacent to the second trench array 120 in the second direction D2.

Referring to FIG. 2, the first to fourth trench arrays 110 to 140 are illustrated with dotted lines in the drawing, but the first to fourth trench arrays 110 to 140 are merely indicated in the drawing for the purpose of describing the present disclosure. Areas of the first to fourth trench arrays 110 to 140 are not defined by dotted line areas shown in the drawing. That is, the first to fourth trench arrays 110 to 140 may be areas corresponding to areas in which the plurality of first trenches 111 to the plurality of fourth trenches 141 are formed.

A width W1 of the first trench array 110 in the first direction D1 and a width W7 of the fourth trench array 140 in the first direction D1 may be smaller than a width W3 of the second trench array 120 in the first direction D1 and a width W5 of the third trench array 130 in the first direction D1. Here, the width W1 of the first trench array 110 in the first direction D1 may correspond to a length of the plurality of first trenches 111 arranged in the first direction D1. In addition, the width W7 of the fourth trench array 140 in the first direction D1 may correspond to a length of the plurality of fourth trenches 141 arranged in the first direction D1. In addition, the width W3 of the second trench array 120 in the first direction D1 may correspond to a length of the second trench 121 in the first direction D1. In addition, the width W5 of the third trench array 130 in the first direction D1 may correspond to a length of the third trench 131 in the first direction D1. In addition, a width W2 of the first trench array 110 in the second direction D2 and a width W8 of the fourth trench array 140 in the second direction D2 may be greater than a width W4 of the second trench array 120 in the second direction D2 and a width W6 of the third trench array 130 in the second direction D2. Here, the width W2 of the first trench array 110 in the second direction D2 may correspond to a length of the first trench 111 in the second direction D2. In addition, the width W8 of the fourth trench array 140 in the second direction D2 may correspond to a length of the fourth trench 141 in the second direction D2. In addition, the width W4 of the second trench array 120 in the second direction D2 may correspond to a length of the plurality of second trenches 121 arranged in the second direction D2. In addition, the width W6 of the third trench array 130 in the second direction D2 may correspond to a length of the plurality of third trenches 131 arranged in the second direction D2. That is, the first cell 100 may have an arrangement structure in which the first to fourth trench arrays 110 to 140 are disposed in a pinwheel shape based on the center of the first cell 100 according to the arrangement structure described above.

In this way, as in the first cell 100, since respective cells constituting a trench capacitor are disposed in a pinwheel shape based on the center of the cells, empty areas between trench arrays are not disposed on a single straight line. Thus, in the capacitor 1000, the trenches may serve to stop or prevent continuous cracks due to external forces or deformation applied along a straight line or in one direction. That is, since the first cell 100 has a pinwheel shape, external forces applied to the center of gravity of the first cell 100 can be distributed to the first to fourth trench arrays 110 to 140 so that the first cell 100 can withstand external forces or deformation well.

Meanwhile, in the capacitor 1000 according to one embodiment of the present disclosure, the number and arrangement structure of the plurality of trenches 111 of the first trench array 110 may be the same as those of the plurality of trenches 141 of the fourth trench array 140. In addition, the number and arrangement structure of the plurality of trenches 121 of the second trench array 120 may be the same as those of the plurality of trenches 131 of the third trench array 130. In addition, the number and arrangement structure of the plurality of trenches 111 of the first trench array 110 may be different from those of the plurality of trenches 121 of the second trench array 120.

However, the present disclosure is not limited thereto, and in some embodiments, the arrangement structure of the first to fourth trench arrays 110 to 140 may be formed in various ways according to a design structure. That is, although the widths W1 and W2 of the first trench array 110 in the first direction D1 and the second direction D2 are illustrated in FIG. 2 as being respectively equal to the widths W7 and W8 of the fourth trench array 140 in the first direction D1 and the second direction D2, but the present disclosure is not limited thereto, and the first trench array 110 and the fourth trench array 140 may have different widths. In addition, although the widths W3 and W4 of the second trench array 120 in the first direction D1 and the second direction D2 are illustrated in FIG. 2 as being respectively equal to the widths W5 and W 6 of the third trench array 130 in the first direction D1 and the second direction D2, but the present disclosure is not limited thereto, and the second trench array 120 and the third trench array 130 may have different widths.

Meanwhile, the first trench array 110 and the fourth trench array 140 include the plurality of first trenches 111 and the plurality of fourth trenches 141 formed in the second direction D2 and arranged in the first direction D1, respectively. In this case, although the first trench array 110 is illustrated in the drawing as including five first trenches 111, the present disclosure is not limited thereto, and the number of trenches may be determined to be different from that shown in the drawing within a range necessary for a design structure.

The second trench array 120 and the third trench array 130 include the plurality of second trenches 121 and the plurality of third trenches 131 formed in the first direction D1 and arranged in the second direction D2, respectively. In this case, although the second trench array 120 is illustrated in the drawing as including six second trenches 121, the present disclosure is not limited thereto, and the number of trenches may be determined to be different from that shown in the drawing within a range necessary for a design structure.

Each of the plurality of first trenches 111 to the plurality of fourth trenches 141 includes a first empty area M1 that separates each of the plurality of first trenches 111 to the plurality of fourth trenches 141 at a first ratio.

Here, when one trench is separated into two piece trenches, the first ratio is a ratio of lengths of the two piece trenches. The first ratio according to one embodiment of the present disclosure may be a different ratio from a ratio of 5:5. That is, the first ratio may be determined such that respective piece trenches have different lengths. Here, when one trench is separated at the first ratio, among respective piece trenches, a piece trench with a relatively long length is defined as a long-side trench, and a piece trench with a relatively short length is defined as a short-side trench. Preferably, a length ratio of a short piece trench to a long piece trench may be in a range of 4:6 to 3:7. For example, the first ratio may be a ratio of 3:7. Accordingly, lengths of respective piece trenches in one trench may be determined to be different. Hereinafter, for convenience of description, the description will be provided on the assumption that the first ratio is a ratio of 3:7.

Referring to FIGS. 1 and 2, for example, since each of the plurality of first trenches 111 to the plurality of fourth trenches 141 is separated at the first ratio, each of the plurality of first trenches 111 to the plurality of fourth trenches 141 may be separated into a plurality of piece trenches. Here, the plurality of piece trenches of each of the plurality of first trenches 111 to the plurality of fourth trenches 141 may be defined as first short-side trenches 111a and first long-side trenches 111b to fourth short-side trenches 141a and fourth long-side trenches 141b according to relative lengths thereof.

The electrical characteristics of the capacitor 1000 can be improved by separating each of the plurality of first trenches 111 to the plurality of fourth trenches 141 at the first ratio. Specifically, equivalent series resistance (ESR) characteristics can be determined according to an area of a metal layer of a capacitor disposed on the substrate 10. Therefore, regarding the electrical characteristics of the capacitor 1000, when each of the plurality of first trenches 111 to the plurality of fourth trenches 141 is separated, and the first empty area M1 is formed in the capacitor 1000, an area of a metal layer on the substrate 10 may be reduced as compared to when each of the plurality of first trenches 111 to the plurality of fourth trenches 141 is not separated. As a result, the ESR characteristics of the capacitor 1000 can be improved.

Meanwhile, when each of the plurality of first trenches 111 to the plurality of fourth trenches 141 is separated at a ratio of 3:7 or 7:3, the electrical characteristics of the capacitor 1000 can be improved as compared to when each of the plurality of first trenches 111 to the plurality of fourth trenches 141 is separated at other ratios.

Hereinafter, the arrangement structure of the plurality of fifth trenches 211 to the plurality of eighth trenches 241 of the capacitor 1000 according to one embodiment of the present disclosure will be described in detail with reference to FIGS. 1 and 3. Here, FIG. 3 is an enlarged view of portion III of FIG. 1. In this case, descriptions overlapping with those provided with reference to FIGS. 1 and 2 will be omitted below.

Referring to FIGS. 1 and 3, each set of the second cells 200 includes one fifth trench array 210 to one eighth trench array 240.

The fifth trench array 210 may be disposed adjacent to the sixth trench array 220 in the first direction D1. In addition, the fifth trench array 210 may be disposed adjacent to the seventh trench array 230 in the second direction D2. In addition, the eighth trench array 240 may be disposed adjacent to the seventh trench array 230 in the first direction D1. In addition, the eighth trench array 240 may be disposed adjacent to the sixth trench array 220 in the second direction D2.

Referring to FIG. 3, the fifth to eighth trench arrays 210 to 240 are illustrated with dotted lines in the drawing, but the fifth to eighth trench arrays 210 to 240 are merely indicated in the drawing for the purpose of describing the present disclosure. Areas of the fifth to eighth trench arrays 210 to 240 are not defined by dotted line areas shown in the drawing. That is, the fifth to eighth trench arrays 210 to 240 may be areas corresponding to areas in which the plurality of fifth trenches 211 to the plurality of eighth trenches 241 are formed.

A width W9 of the fifth trench array 210 in the first direction D1 and a width W15 of the eighth trench array 240 in the first direction D1 may be smaller than a width W11 of the sixth trench array 220 in the first direction D1 and a width W13 of the seventh trench array 230 in the first direction D1. Here, the width W9 of the fifth trench array 210 in the first direction D1 may correspond to a length of the plurality of fifth trenches 211 arranged in the first direction D1. In addition, the width W15 of the eighth trench array 240 in the first direction D1 may correspond to a length of the plurality of eighth trenches 241 arranged in the first direction D1. In addition, the width W11 of the sixth trench array 220 in the first direction D1 may correspond to a length of the sixth trench 221 in the first direction D1. In addition, the width W13 of the seventh trench array 230 in the first direction D1 may correspond to a length of the seventh trench 231 in the first direction D1.

In addition, a width W10 of the fifth trench array 210 in the second direction D2 and a width W16 of the eighth trench array 240 in the second direction D2 may be greater than a width W12 of the sixth trench array 220 in the second direction D2 and a width W14 of the seventh trench array 230 in the second direction D2. Here, the width W10 of the fifth trench array 210 in the second direction D2 may correspond to a length of the fifth trench 211 in the second direction D2. In addition, the width W16 of the eighth trench array 240 in the second direction D2 may correspond to a length of the eighth trench 241 in the second direction D2. In addition, the width W12 of the sixth trench array 220 in the second direction D2 may correspond to a length of the plurality of sixth trenches 221 arranged in the second direction D2. In addition, the width W14 of the seventh trench array 230 in the second direction D2 may correspond to ae length of the plurality of seventh trenches 231 arranged in the second direction D2. That is, the second cell 200 may have an arrangement structure in which the fifth to eighth trench arrays 210 to 240 are arranged in a pinwheel shape according to the arrangement structure described above.

The second cell 200 may have a pinwheel-shaped arrangement structure of the fifth to eighth trench arrays 210 to 240 and thus may withstand external forces or deformation applied to the capacitor 1000 as described above.

Meanwhile, in the capacitor 1000 according to one embodiment of the present disclosure, the number and arrangement structure of the plurality of trenches 211 of the fifth trench array 210 may be the same as those of the plurality of trenches 241 of the eighth trench array 240. In addition, the number and arrangement structure of the plurality of trenches 221 of the sixth trench array 220 may be the same as those of the plurality of trenches 231 of the seventh trench array 230. In addition, the number and arrangement structure of the plurality of trenches 211 of the fifth trench array 210 may be different from those of the plurality of trenches 221 of the sixth trench array 220.

However, the present disclosure is not limited thereto, and in some embodiments, the arrangement structure of the fifth to eighth trench arrays 210 to 240 may be formed in various ways according to a design structure. That is, although the widths W9 and W10 of the fifth trench array 210 in the first direction D1 and the second direction D2 are illustrated in FIG. 3 as being respectively equal to the widths W15 and W16 of the eighth trench array 240 in the first direction D1 and the second direction D2, but the present disclosure is not limited thereto, and the fifth trench array 210 and the eighth trench array 240 may have different widths. That is, although the widths W11 and W12 of the sixth trench array 220 in the first direction D1 and the second direction D2 are illustrated in FIG. 3 as being respectively equal to the widths W13 and W14 of the seventh trench array 230 in the first direction D1 and the second direction D2, but the present disclosure is not limited thereto, and the sixth trench array 220 and the seventh trench array 230 may have different widths.

The fifth trench array 210 and the eighth trench array 240 include the plurality of fifth trenches 211 and the plurality of eighth trenches 241 formed in the second direction D2 and arranged in the first direction D1, respectively. In this case, although the fifth trench array 210 is illustrated in the drawing as including five fifth trenches 211, the present disclosure is not limited thereto, and the number of trenches may be determined to be different from that shown in the drawing within a range necessary for a design structure.

The sixth trench array 220 and the seventh trench array 230 include the plurality of sixth trenches 221 and the plurality of seventh trenches 231 formed in the first direction D1 and arranged in the second direction D2, respectively. In this case, although the sixth trench array 220 is illustrated in the drawing as including six sixth trenches 221, the present disclosure is not limited thereto, and the number of trenches may be determined to be different from that shown in the drawing within a range necessary for a design structure.

Here, in the capacitor 1000, the number of the plurality of first trenches 111 may be the same as the number of the plurality of fifth trenches 211. In addition, in the capacitor 1000, the number of the plurality of second trenches 121 may be the same as the number of the plurality of sixth trenches 221. In addition, in the capacitor 1000, the number of the plurality of third trenches 131 may be the same as the number of the plurality of seventh trenches 231. In addition, in the capacitor 1000, the number of the plurality of fourth trenches 141 may be the same as the number of the plurality of eighth trenches 241.

Each of the plurality of fifth trenches 211 to the plurality of eighth trenches 241 includes a second empty area M2 that separates each of the plurality of fifth trenches 211 to the plurality of eighth trenches 241 at a second ratio.

Here, when one trench is separated into two piece trenches, the second ratio is a ratio of lengths of the two piece trenches. In addition, the second ratio may be a different ratio from the first ratio. In addition, the second ratio according to one embodiment of the present disclosure may be a different ratio from a ratio of 5:5. That is, the second ratio may be determined such that respective piece trenches have different lengths. Here, when one trench is separated at the second ratio, among respective piece trenches, a piece trench with a relatively long length is defined as a long-side trench, and a piece trench with a relatively short length is defined as a short-side trench. Preferably, a length ratio of a long piece trench to a short piece trench may be in a range of 6:4 to 7:3. For example, the second ratio may be a ratio of 7:3. In addition, the second ratio may be a ratio that is complementary to the first ratio. For example, when the first ratio is a ratio of 3:7, the second ratio may be a ratio of 7:3. Accordingly, lengths of respective piece trenches in one trench may be determined to be different. Hereinafter, for convenience of description, the description will be provided on the assumption that the first ratio is a ratio of 3:7 and the second ratio is a ratio of 7:3.

Referring to FIGS. 1 and 3, for example, since each of the plurality of fifth trenches 211 to the plurality of eighth trenches 241 is separated at the second ratio, each of the plurality of fifth trenches 211 to the plurality of eighth trenches 241 may be separated into a plurality of piece trenches. Here, the plurality of piece trenches of each of the plurality of fifth trenches 211 to the plurality of eighth trenches 241 may be defined as fifth long-side trenches 211a and fifth short-side trenches 211b to eighth long-side trenches 241a and eighth short-side trenches 241b according to relative lengths thereof.

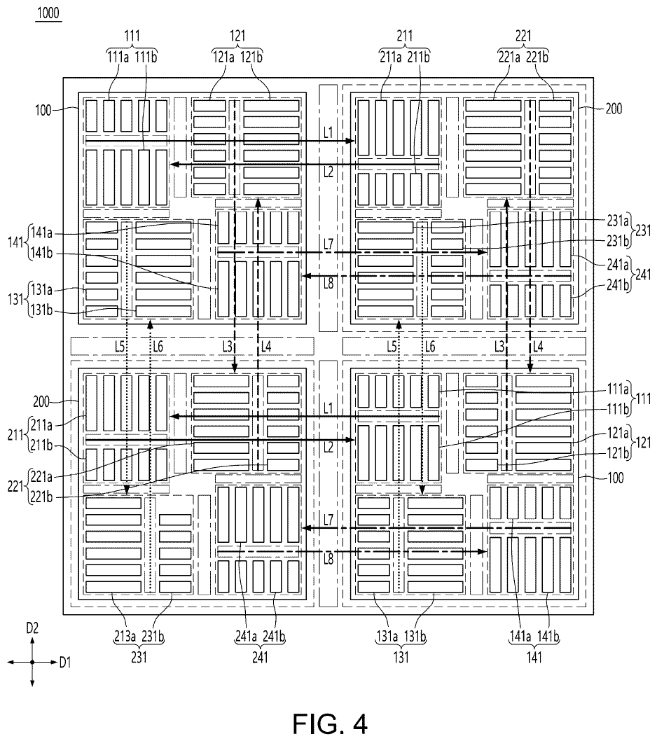

Meanwhile, the capacitor 1000 may withstand external forces or deformation well because the second ratio is a different ratio from the first ratio. Specific details thereof will be described below with reference to FIG. 4. In addition, as described above, the electrical characteristics of the capacitor 1000 can be improved by separating each of the plurality of fifth trenches 211 to the plurality of eighth trenches 241 at the second ratio.

Hereinafter, with reference to FIGS. 1 to 4, the reason why the capacitor 1000 according to one embodiment of the present disclosure has a structure that is resistant to external forces and deformation will be described in detail. Here, FIG. 4 is a plan view of the capacitor 1000 illustrating an extension line passing through the center of an empty area of the capacitor 1000 according to one embodiment of the present disclosure. In this case, descriptions overlapping with those provided with reference to FIGS. 1 to 3 will be omitted below.

Referring to FIGS. 1 to 4, in the capacitor 1000, the plurality of first cells 100 and the plurality of second cells 200 may be alternately disposed adjacent to each other in the first direction D1 and the second direction D2.

Since the plurality of first cells 100 and the plurality of second cells 200 are alternately disposed adjacent to each other in the first direction D1 and the second direction D2, the capacitor 1000 according to one embodiment of the present disclosure can withstand external forces or deformation well. In addition, since each of the plurality of trenches 111 to 141 is separated at the first ratio, each of the plurality of trenches 211 to 241 is separated at the second ratio, and the first ratio and the second ratio are different ratios, the capacitor 1000 according to one embodiment of the present disclosure can withstand external forces or deformation.

Referring to FIGS. 2 to 4 for detailed descriptions thereof, the plurality of first trenches 111 and the plurality of fifth trenches 211 may be disposed such that a first extension line L1 in the first direction D1 passing through the center of the first empty area M1 formed in the first trenches 111 of the first cell 100 is offset from a second extension line L2 in the first direction D1 passing through the center of the second empty area M2 formed in the fifth trenches 211 of the second cell 200. In addition, the plurality of second trenches 121 and the plurality of sixth trenches 221 may be disposed such that a third extension line L3 in the second direction D2 passing through the center of the first empty area M1 formed in the second trenches 121 of the first cell 100 is offset from a fourth extension line L4 in the second direction D2 passing through the center of the second empty area M2 formed in the sixth trenches 221 of the second cell 200. In addition, the plurality of third trenches 131 and the plurality of seventh trenches 231 may be disposed such that a fifth extension line L5 in the second direction D2 passing through the center of the first empty area M1 formed in the third trenches 131 of the first cell 100 is offset from an eighth extension line L8 in the second direction D2 passing through the center of the second empty area M2 formed in the seventh trenches 231 of the second cell 200. In addition, the plurality of fourth trenches 141 and the plurality of eighth trenches 241 may be disposed such that a seventh extension line L7 in the first direction D1 passing through the center of the first empty area M1 formed in the fourth trenches 141 of the first cell 100 is offset from the eighth extension line L8 in the first direction D1 passing through the center of the second empty area M2 formed in the eighth trenches 241 of the second cell 200.

That is, in the capacitor 1000 according to one embodiment of the present disclosure, since the first trenches 111 to the eighth trenches 241 are disposed in the structure described above, the trenches 111 to 141 and 211 to 241 perpendicular to the extension lines L1 to L8 may be disposed in directions in which the extension lines L1 to L8 extend. Therefore, in the capacitor 1000, cracks, which are caused by external forces applied in longitudinal directions in which the first to eighth extension lines L1 to L8 extend, can be stopped by the trenches 111 to 141 and 211 to 241 disposed perpendicular to the longitudinal directions. As a result, the capacitor 1000 may have a crack stop structure due to the above-described arrangement structure, and external forces applied in one direction of the capacitor 1000 can be distributed to the trenches 111 to 141 and 211 to 241, thereby enabling the capacitor 1000 to withstand external forces and deformation well.

FIG. 5 is a partial plan view of the capacitor 1000 illustrating a plurality of metal contacts 400 according to one embodiment of the present disclosure. FIG. 6 is a plan view of the capacitor 1000 illustrating the plurality of metal contacts 400 according to one embodiment of the present disclosure.

Referring to FIGS. 1 to 3, 5, and 6, the capacitor 1000 according to one embodiment of the present disclosure further includes the plurality of metal contacts 400. Hereinafter, the plurality of metal contacts 400 formed in the capacitor 1000 will be described with reference to FIGS. 1 to 3, 5, and 6. In this case, descriptions overlapping with those provided with reference to FIGS. 1 and 3 will be omitted below.

However, in the present specification, in order to clearly describe positions at which the plurality of metal contacts 400 are formed, first, the first to fifth support bar areas 310 to 350 in the capacitor 1000 will be described.

Referring to FIGS. 1 to 3, 5, and 6, the first support bar area 310 may be a separation area formed as the plurality of first cells 100 and the plurality of second cells 200 are disposed to be spaced apart from each other in the second direction D2. The second support bar area 320 may be a separation area formed as the trench arrays 110 to 140 and 210 to 240 are disposed to be spaced apart from each other in the second direction D2 in the first cell 100 and the second cell 200. The third support bar area 330 may be a separation area formed as the plurality of first cells 100 and the plurality of second cells 200 are disposed to be spaced apart from each other in the first direction D1. The fourth support bar area 340 may refer to a separation area formed as the trench arrays 110 to 140 and 210 to 240 are disposed to be spaced apart from each other in the first direction D1 in the first cell 100 and the second cell 200. The fifth support bar area 350 may be an area corresponding to the first empty area M1 in the plurality of first trenches 111 to the plurality of fourth trenches 141 or the second empty area M2 in the plurality of fifth trenches 211 to the plurality of eighth trenches 241.

Meanwhile, the first to fifth support bar areas 310 to 350 may have different widths. That is, the first to fifth support bar areas 310 to 350 may be formed to have different widths on the premise that a minimum process margin required for designing a manufacturing process of the capacitor 1000 is secured within a limited area of the substrate 10. In this case, since the first to fifth support bar areas 310 to 350 of the capacitor 1000 are formed to have different widths, the trenches 111 to 141 and 211 to 241 can be efficiently disposed in the limited area of the substrate 10, and the integration density of the capacitor 1000 can be improved as compared to a capacitor in which the first to fifth support bar areas 310 to 350 have the same width.

Specifically, in the capacitor 1000, the first to fifth support bar areas 310 to 350 are formed to have different widths, thereby reducing an unnecessary area of the substrate 10 allocated to the support bar area. As a result, a large number of trenches 111 to 141 and 211 to 24 are disposed in the limited area of the substrate 10, thereby improving the integration density of the capacitor 1000. In some embodiments of the present disclosure, the first to third support bar areas 310 to 330 may have the same width. However, the widths of the first to fifth support bar areas 310 to 350 may all be the same according to arrangement intervals between the trenches 111 to 141 and 211 to 241 and a process design.

As described above, according to embodiments of the present disclosure, by diversifying the widths of the first to fifth support bar areas 310 to 350, pattern structures of the trenches 111 to 141 and 211 to 241 can be variously formed in a plane view. The pattern structures of the trenches 111 to 141 and 211 to 241 are variously formed to be as close to an irregular shape as possible, thereby suppressing damage or breakage of the capacitor 1000 due to external forces or deformation applied in one direction, and also reducing the size of an area of the capacitor 1000 which is damaged or broken. Furthermore, by diversifying the widths of the first to fifth support bar areas 310 to 350, the arrangement between the plurality of trenches 111 to 141 and 211 to 241 and the plurality of metal contacts 400 can be optimized, thereby securing a margin required for a manufacturing process of the capacitor 1000 in various ways. In addition, by adjusting a design margin in various ways, ESR characteristics can be improved while many capacitors 1000 are disposed on the limited substrate 10. Hereinafter, in the present specification, the arrangement structure of the plurality of metal contacts 400 will be described in detail with reference to FIGS. 5 and 6.

In the present specification, in order to describe the arrangement structure of the plurality of metal contacts 400, first, first virtual center lines VCL1 and second virtual center lines VCL2 are defined with reference to FIG. 5.

The first virtual center lines VCL1 are virtual lines that pass through the centers between the plurality of trenches 111 to 141 and 211 to 241 disposed adjacent to each other in the first to eighth trench arrays 110 to 240 and extend in an extending direction of each of the plurality of trenches 111 to 141 and 211 to 241.

The second virtual center lines VCL2 are virtual lines that pass through the centers of the first to fifth support bar areas 310 to 350 and extend in an extending direction of each of the first to fifth support bar areas 310 to 350.

Referring to FIGS. 5 and 6, the plurality of metal contacts 400 may be formed at points at which a plurality of first virtual center lines VCL1 intersect a plurality of second virtual center lines VCL2. In addition, the plurality of metal contacts 400 may be formed in the first to fifth support bar areas 310 to 350 along each of the plurality of second virtual center lines VCL2.

In addition, each of the plurality of metal contacts 400 may be formed in electrical contact with only one of a plurality of electrode layers of a capacitor layer described below in each of the first to fifth support bar areas 310 to 350. A detailed description thereof will be provided below with reference to FIGS. 7 to 13.

In the capacitor 1000, a minimum margin required for a manufacturing process of the capacitor 1000 is secured through the above-described arrangement structure of the plurality of metal contacts 400, thereby reducing process defects caused by non-uniform etching or deposition. For example, among the plurality of metal contacts 400, each of a plurality of metal contacts 450a formed in a first area 350a of the fifth support bar area, which will be described below, may be formed to be offset from extension lines in an extending direction of each of the plurality of first trenches 111 in the first trench array 110. That is, each of the plurality of metal contacts 450a formed in the first area 350a of the fifth support bar area may not be formed in a space between the first short-side trench 111a and the first long-side trench 111b. Therefore, in the capacitor 1000, even when non-uniform etching or deposition occurs on each of the plurality of metal contacts 450a formed in the first area 350a of the fifth support bar area, it does not affect a trench pattern structure, thereby reducing process defects of the trench pattern structure.

In addition, the ESR of the capacitor 1000 which is the electrical characteristic of the capacitor 1000 can be improved through the above-described arrangement structure of the plurality of metal contacts 400. That is, since each of the plurality of metal contacts 400 of the capacitor 1000 is disposed to be offset from an extension line in an extending direction of each of the plurality of trenches 111 to 141 and 211 to 241, a leakage current flowing to the plurality of metal contacts 400 from a capacitor layer stacked along the plurality of trenches 111 to 141 and 211 to 241 is reduced, thereby improving the ESR characteristics of the capacitor 1000.

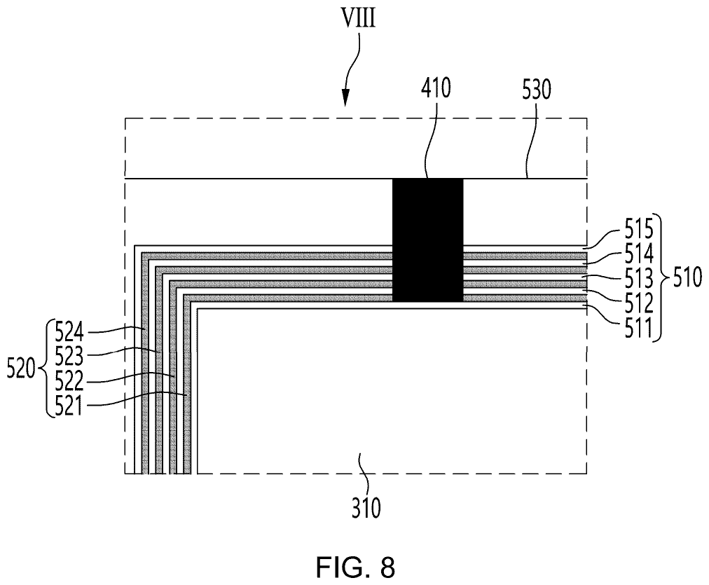

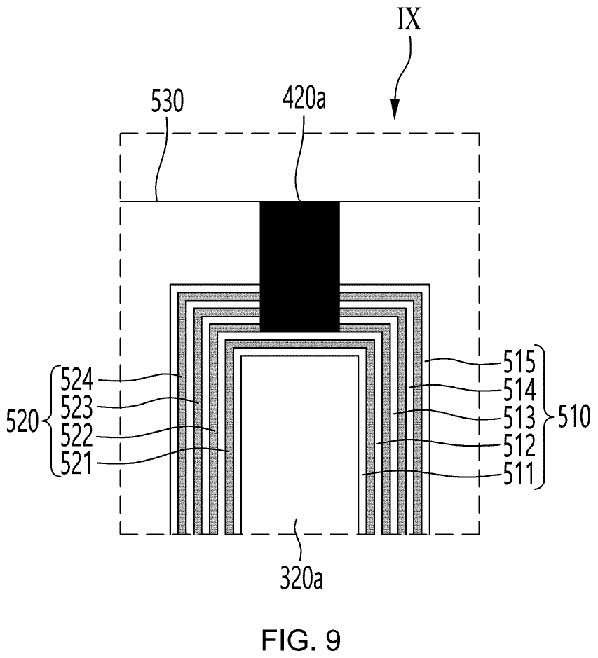

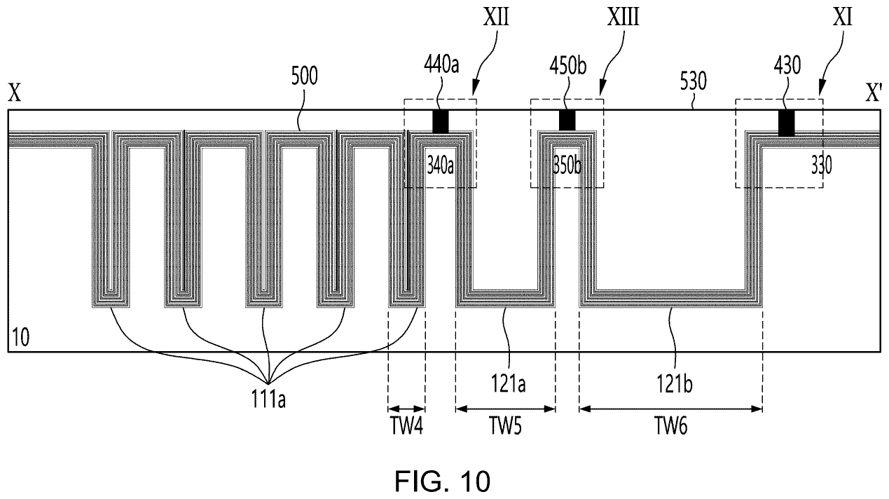

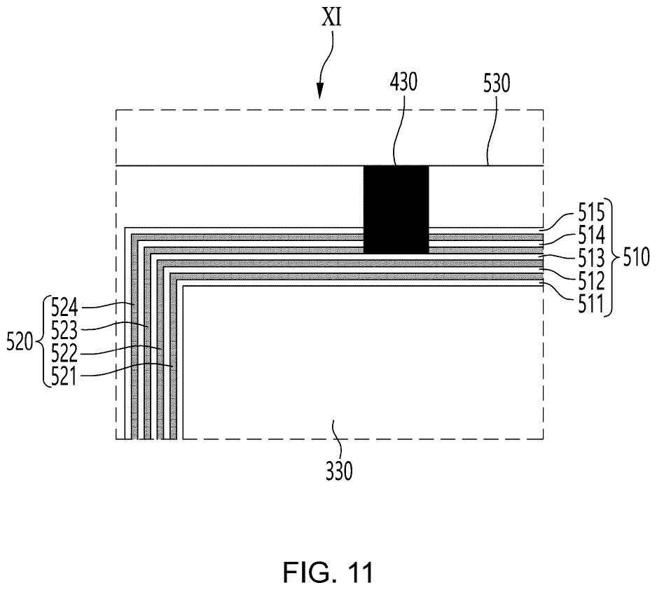

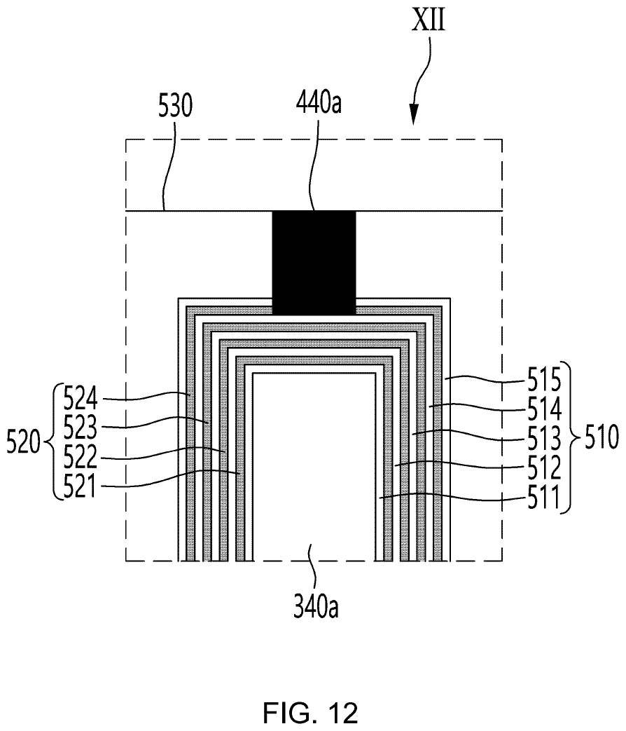

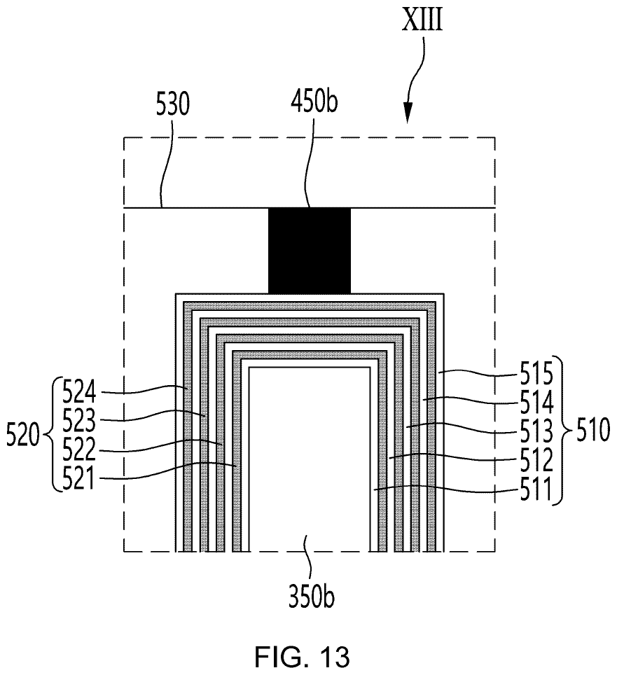

Hereinafter, in the present specification, which electrode layer 510 of the capacitor layer 500 is in electric contact with each of the plurality of metal contacts 400 in each of the first to fifth support bar areas 310 to 350 will be described with reference to FIGS. 1 and 6 to 13. Here, FIG. 7 is a cross-sectional view along line VII-VII′ of FIG. 6. FIG. 8 is an enlarged view of portion VIII of FIG. 7. FIG. 9 is an enlarged view of portion IX of FIG. 7. FIG. 10 is a cross-sectional view along line X-X′ of FIG. 6. FIG. 11 is an enlarged view of portion XI of FIG. 10. FIG. 12 is an enlarged view of portion XII of FIG. 10. FIG. 13 is an enlarged view of portion XIII of FIG. 10.

Referring to FIGS. 1 and 7 to 13, the capacitor 1000 according to one embodiment of the present disclosure further includes the capacitor layer 500. The capacitor layer 500 includes first to fifth electrode layers 511 to 515, first to fourth dielectric layers 521 to 524, and an insulating layer 530. However, the present disclosure is not limited thereto, and the capacitor layer 500 may include N electrode layers 510 and N-1 dielectric layers 520 according to a design structure.

The capacitor layer 500 may have a structure in which a plurality of electrode layers 510 and a plurality of dielectric layers 520 are alternately stacked. That is, the capacitor layer 500 may have a metal-insulator-metal-insulator-metal . . . (MIMIM . . . ) structure. Hereinafter, for convenience of description, the description will be provided on the assumption that the capacitor layer 500 includes five electrode layers 510 and four dielectric layers 520.

The first electrode layer 511 may be disposed on the substrate 10 along the first trenches 111 to the eighth trenches 241. In addition, the first dielectric layer 521 may be disposed on the first electrode layer 511. In addition, the second electrode layer 512 may be disposed on the first dielectric layer 521. In addition, the second dielectric layer 522 may be disposed on the second electrode layer 512. In addition, the third electrode layer 513 may be disposed on the second dielectric layer 522. In addition, the third dielectric layer 523 may be disposed on the third electrode layer 513. In addition, the fourth electrode layer 514 may be disposed on the third dielectric layer 523. In addition, the fourth dielectric layer 524 may be disposed on the fourth electrode layer 514. In addition, the fifth electrode layer 515 may be disposed on the fourth dielectric layer 524. Thereafter, the insulating layer 530 may be disposed on the fifth electrode layer 515.

The plurality of electrode layers 510 may be formed of a metallic material. For example, the plurality of electrode layers 510 may be formed of a compound including or consisting of at least one of copper, titanium nitride, aluminum, or tungsten. The plurality of dielectric layers 520 may be formed of titanium oxide, zirconium oxide, aluminum oxide, and zirconium oxide. The insulating layer 530 may be formed of an insulating material. For example, the insulating layer 530 may be formed of a material such as SiO, SiON, AlO, AlON, or ZrO. However, the present disclosure is not limited thereto, and each of the plurality of electrode layers 510, the plurality of dielectric layers 520, and the insulating layer 530 may be formed of other materials that can be selected according to the characteristics of the layer.

Meanwhile, referring to FIGS. 1 and 6 to 13, the plurality of metal contacts 400 include a plurality of first metal contacts 410 to a plurality of fifth metal contacts 450. Meanwhile, the plurality of metal contacts 400 may be formed of a metallic material to have high conductivity.

Referring to FIGS. 7 to 13, each of the plurality of metal contacts 400 may be formed in electric contact with one electrode layer of the electrode layers 511 to 515 among the plurality of electrode layers 510 of the capacitor layer 500 in each of the first to fifth support bar areas 310 to 350. That is, each of the plurality of metal contacts 400 may be formed in contact with any one electrode layer of the plurality of electrode layers 510 of the capacitor layer 500 in each of the first to fifth support bar areas 310 to 350. Specifically, the plurality of first metal contacts 410 may be formed such that only the first electrode layer 511 is in contact with a lower surface of the first metal contact 410 in the first support bar area 310. In addition, the plurality of second metal contacts 420 may be formed such that only the second electrode layer 512 is in contact with a lower surface of the second metal contact 420 in the second support bar area 320. In addition, the plurality of third metal contacts 430 may be formed such that only the third electrode layer 513 is in contact with a lower surface of the third metal contact 430 in the third support bar area 330. In addition, the plurality of fourth metal contacts 440 may be formed such that only the fourth electrode layer 514 is in contact with a lower surface of the fourth metal contact 440 in the fourth support bar area 340. In addition, the plurality of fifth metal contacts 450 may be formed such that only the fifth electrode layer 515 is in contact with a lower surface of the fifth metal contact 450 in the fifth support bar area 350.

For example, referring to FIGS. 7 and 8, the plurality of first metal contacts 410 may be formed in electrical contact with the first electrode layer 511 in the first support bar area 310.

Referring to FIGS. 7 and 9, a plurality of second metal contacts 420a formed in a first area 320a of the second support bar area among the plurality of metal contacts 400 may be formed in electric contact with the second electrode layer 512.

Referring to FIGS. 10 and 11, the plurality of third metal contacts 430 may be formed in electric contact with the third electrode layer 513 in the third support bar area 330.

Referring to FIGS. 10 and 12, a plurality of fourth metal contacts 440a formed in a first area 340a of the fourth support bar area among the plurality of metal contacts 400 may be formed in electrical contact with the fourth electrode layer 514.

Referring to FIGS. 10 and 13, a plurality of fifth metal contacts 450b formed in a second area 350b of the fifth support bar area among the plurality of metal contacts 400 may be formed in electrical contact with the fifth electrode layer 515.

That is, in the capacitor 1000, by forming the capacitor layer 500 including the plurality of electrode layers 510 and the plurality of dielectric layers 520, various capacitances can be provided in the limited area of the substrate 10.

In addition, the capacitor 1000 is formed such that the plurality of first metal contacts 410 to the plurality of fifth metal contacts 450 are in electrical contact with the first electrode layer 511 to the fifth electrode layer 515, thereby improving the electrical characteristics of the capacitor 1000. For example, in the capacitor 1000, by forming a metal pattern that is electrically connected to the first electrode layer 511 through the plurality of first metal contacts 410, a voltage may be applied only to the first electrode layer 511 in an area in which the plurality of first metal contacts 410 are formed, and a voltage may not be applied to the second to fifth electrode layers 512 to 515 other than the first electrode layer 511. That is, in the capacitor 1000, a leakage current due to a voltage applied to the first electrode layer 511 does not occur outside the area in which the plurality of first metal contacts 410 are formed, thereby improving the electrical characteristics of the capacitor 1000.

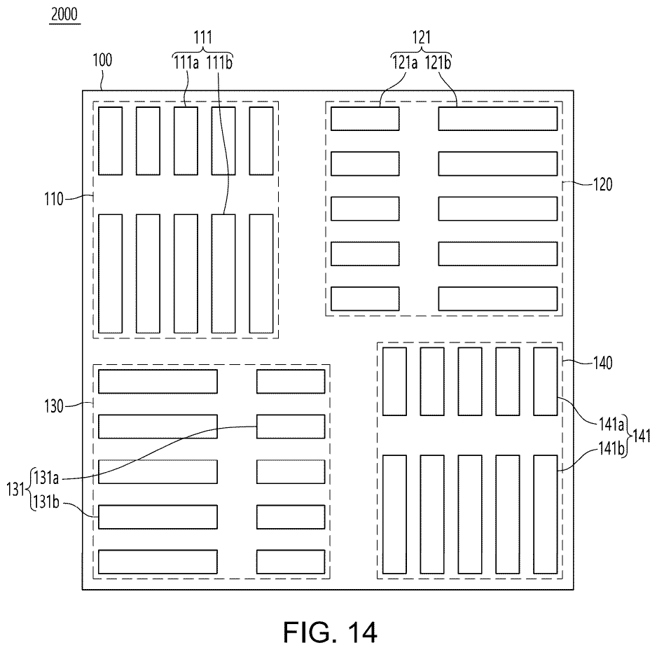

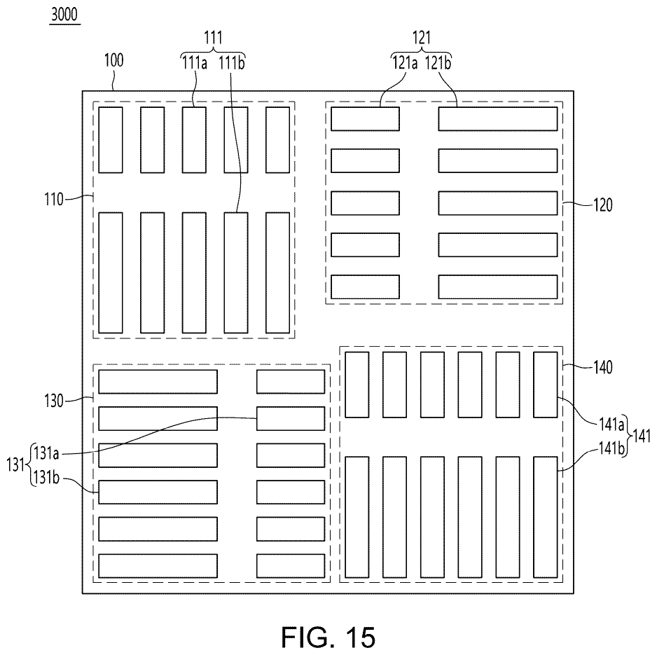

The pattern structure of the plurality of trenches 111 to 141 and 211 to 241 of the capacitor may vary in some embodiments. In the present specification, some embodiments will be described in detail with reference to FIGS. 14 and 15. In this case, descriptions overlapping with those provided with reference to FIGS. 1 and 13 will be omitted below.

FIG. 14 is a plan view of one cell of a capacitor 2000 according to another embodiment of the present disclosure.

Referring to FIG. 14, in the capacitor 2000 according to another embodiment of the present disclosure, the numbers of a plurality of first trenches 111 to a plurality of fourth trenches 141 may be the same in each set of a plurality of first cells 100. In the capacitor 2000 according to another embodiment of the present disclosure, the number of the plurality of first trenches 111 may be the same as the number of the plurality of fifth trenches 211. In addition, in the capacitor 2000, the number of second trenches 121 may be the same as the number of sixth trenches 221. In addition, in the capacitor 2000, the number of third trenches 131 may be the same as the number of seventh trenches 231. In addition, in the capacitor 2000, the number of fourth trenches 141 may be the same as the number of eighth trenches 241.

Since respective trench arrays are disposed in a symmetrical pinwheel structure, the capacitor 2000 according to another embodiment of the present disclosure can withstand externals force or deformation well. Specifically, in the capacitor 2000 according to another embodiment of the present disclosure, since respective cells constituting the capacitor 2000 are disposed in a pinwheel shape based on the center of the cells, empty areas between the trench arrays are not disposed on a single straight line. Therefore, in the capacitor 2000, the trenches may serve to stop or prevent continuous cracks due to external forces or deformation applied along a straight line or in one direction to the capacitor 2000. That is, since the capacitor 2000 has a pinwheel shape as shown in FIG. 14, external forces applied to the capacitor 2000 can be distributed to the trenches, thereby withstanding external forces or deformation well.

FIG. 15 is a plan view of one cell of a capacitor 3000 according to still another embodiment of the present disclosure.

Referring to FIG. 15, in the capacitor 3000 according to another embodiment of the present disclosure, the number of a plurality of first trenches 111 and the number of a plurality of second trenches 121 may be the same in each set of a plurality of first cells 100. In addition, in the capacitor 3000, the number of third trenches 131 may be the same as the number of fourth trenches 141. However, in the capacitor 3000, the number of the plurality of first trenches 111 may be different from the number of the plurality of third trenches 131.

In the capacitor 3000 according to still another embodiment of the present disclosure, since respective cells constituting the capacitor 3000 are disposed in a pinwheel shape based on the center of the cells, empty areas between the trench arrays are not disposed on a single straight line. Therefore, in the capacitor 3000, the trenches may serve to stop or prevent continuous cracks due to external forces or deformation applied along a straight line or in one direction to the capacitor 3000. That is, since the capacitor 3000 has a pinwheel shape as shown in FIG. 15, external forces applied to the capacitor 3000 can be distributed to the trenches, thereby withstanding external forces or deformation well.

In addition, since each of trench arrays is disposed in an asymmetrical pinwheel structure, the capacitor 3000 according to still another embodiment of the present disclosure can withstand external forces or deformation well as compared to a trench pattern structure formed in a symmetrical pinwheel structure. Specifically, in the capacitor 3000 according to still another embodiment of the present disclosure, since each trench array is formed in an asymmetrical pinwheel structure, the center of gravity of the capacitor 3000 is biased in a specific direction. That is, when the capacitor 3000 is mounted on an electronic circuit, since external forces applied to the center of the capacitor 3000 do not coincide with the center of gravity of the capacitor 3000 according to still another embodiment of the present disclosure having an asymmetric pinwheel pattern structure, the capacitor 3000 can withstand external forces or deformation well as compared to a capacitor having a symmetric pinwheel trench pattern structure in which the center of gravity is formed at the center of the capacitor. In addition, since the arrangement structure of the trench arrays of the capacitor 3000 is formed asymmetrically, the capacitance of the capacitor 3000 determined by an area of the trench arrays can be determined in various ways as compared to a capacitor of which trench arrays have a symmetrical arrangement structure. That is, the capacitor 3000 can provide various capacitances as compared to a capacitor of which trench arrays have a symmetrical arrangement structure.

Referring to FIGS. 1 to 15, in the capacitors 1000, 2000, and 3000, various components can be appropriately disposed on the limited substrate 10 through the arrangement structure described above so that many capacitors 1000, 2000, and 3000 can be disposed in the limited area of the substrate 10, and the integration density of the capacitors 1000, 2000, and 3000 can be improved.

According to any one of the means for solving the problems of the present disclosure, it is possible to provide a capacitor that can withstand external forces or deformation through a pattern structure of a plurality of trenches formed in a substrate.

In addition, according to any one of the means for solving the problems of the present disclosure, a leakage current due to an increase in integration density of capacitors can be reduced, and equivalent series resistance (ESR), which is an electrical characteristic of the capacitor, can be improved.

In addition, according to any one of the means for solving the problems of the present disclosure, the arrangement between a pattern of a plurality of trenches and a metal contact of a capacitor is adjusted, thereby securing a margin required for a manufacturing process of the capacitor. Furthermore, it is possible to reduce defects caused by non-uniform etching or deposition that occur during a manufacturing process of a capacitor.

In addition, according to any one of the means for solving the problems of the present disclosure, by including an arrangement structure that is resistant to external forces or deformation, many capacitors can be disposed on a limited substrate, thereby improving the integration density and capacitance of capacitors.

The effects obtainable in the present disclosure are not limited to the effects described above, and other effects that are not described will be clearly understood by a person skilled in the art from the description below.

Although embodiments of the present disclosure have been described in more detail with reference to the accompanying drawings, the present disclosure is not necessarily limited to these embodiments, and various modifications may be made without departing from the technical spirit of the present disclosure. Accordingly, the embodiments disclosed in the present disclosure are not intended to limit the technical idea of the present disclosure but are for illustrative purposes, and the scope of the technical idea of the present disclosure is not limited by these embodiments. Accordingly, it should be understood that the above-described embodiments are exemplary in all respects and not restrictive. The spirit and scope of the present disclosure should be interpreted by the appended claims and encompass all equivalents falling within the scope of the appended claims.

What is claimed is:

1. A capacitor comprising a plurality of first cells,
wherein each of the plurality of first cells includes:
a first trench array including a plurality of first trenches formed in a second direction on a substrate;
a second trench array including a plurality of second trenches formed in a first direction on the substrate;
a third trench array including a plurality of third trenches formed in the first direction on the substrate;
a fourth trench array including a plurality of fourth trenches formed in the second direction on the substrate; and
a capacitor layer including at least two electrode layers and at least one dielectric layer,
wherein each of the plurality of first trenches and each of the plurality of fourth trenches are arranged in the first direction,
each of the plurality of second trenches and each of the plurality of third trenches are arranged in the second direction,
each of the plurality of first trenches to the plurality of fourth trenches includes a first empty area configured to separate each of the plurality of first trenches to the plurality of fourth trenches at a first ratio,
the first trench array is disposed adjacent to the second trench array in the first direction and disposed adjacent to the third trench array in the second direction,
the fourth trench array is disposed adjacent to the third trench array in the first direction and disposed adjacent to the second trench array in the second direction, and
the capacitor layer is disposed on the substrate along the plurality of first trenches to the plurality of fourth trenches.

2. The capacitor of claim 1, further comprising a plurality of second cells,
wherein each of the plurality of second cells includes:
a fifth trench array including a plurality of fifth trenches formed in the second direction on the substrate;
a sixth trench array including a plurality of sixth trenches formed in the first direction on the substrate;
a seventh trench array including a plurality of seventh trenches formed in the first direction on the substrate;
an eighth trench array including a plurality of eighth trenches formed in the second direction on the substrate; and
the capacitor layer,
wherein each of the plurality of fifth trenches and each of the plurality of eighth trenches are arranged in the first direction,
each of the plurality of sixth trenches and each of the plurality of seventh trenches are arranged in the second direction,
each of the plurality of fifth trenches to the plurality of eighth trenches includes a second empty area configured to separate each of the plurality of fifth trenches to the plurality of eighth trenches at a second ratio,
the fifth trench array is disposed adjacent to the sixth trench array in the first direction and disposed adjacent to the seventh trench array in the second direction,
the eighth trench array is disposed adjacent to the seventh trench array in the first direction and disposed adjacent to the sixth trench array in the second direction, and
the capacitor layer is disposed on the substrate along the fifth to eighth trenches.

3. The capacitor of claim 2, wherein the first ratio is a ratio that is complementary to the second ratio.

4. The capacitor of claim 2, wherein, in the capacitor,
the number of the plurality of first trenches is the same as the number of the plurality of fifth trenches,
the number of the plurality of second trenches is the same as the number of the plurality of sixth trenches,
the number of the plurality of third trenches is the same as the number of the plurality of seventh trenches, and
the number of the plurality of fourth trenches is the same as the number of the plurality of eighth trenches.

5. The capacitor of claim 4, wherein, in each of the plurality of first cells,
the number of the plurality of first trenches is the same as the number of the plurality of fourth trenches,
the number of the plurality of second trenches is the same as the number of the plurality of third trenches, and
the number of the plurality of first trenches is different from the number of the plurality of second trenches.

6. The capacitor of claim 4, wherein, in each of the plurality of first cells, the numbers of the plurality of first trenches to the plurality of fourth trenches are the same.

7. The capacitor of claim 4, wherein, in each of the plurality of first cells,
the number of the plurality of first trenches is the same as the number of the plurality of second trenches,
the number of the plurality of third trenches is the same as the number of the plurality of fourth trenches, and
the number of the plurality of first trenches is different from the number of the plurality of third trenches.

8. The capacitor of claim 2, wherein the capacitor includes at least two sets of the plurality of first cells and at least two sets of the plurality of second cells.

9. The capacitor of claim 8, wherein the plurality of first cells and the plurality of second cells are alternately disposed adjacent to each other in the first direction and the second direction.

10. The capacitor of claim 9, wherein the plurality of first trenches and the plurality of fifth trenches are disposed such that a first extension line in the first direction passing through a center of a first empty area formed in the plurality of first trenches is offset from a second extension line in the first direction passing through a center of a second empty area formed in the plurality of fifth trenches,
the plurality of second trenches and the plurality of sixth trenches are disposed such that a third extension line in the second direction passing through a center of the first empty area formed in the plurality of second trenches is offset from a fourth extension line in the second direction passing through a center of the second empty area formed in the plurality of sixth trenches,
the plurality of third trenches and the plurality of seventh trenches are disposed such that a fifth extension line in the second direction passing through a center of the first empty area formed in the plurality of third trenches is offset from a sixth extension line in the second direction passing through a center of the second empty area formed in the plurality of seventh trenches, and
the plurality of fourth trenches and the plurality of eighth trenches are disposed such that a seventh extension line in the first direction passing through a center of the first empty area formed in the plurality of fourth trenches is offset from an eighth extension line in the first direction passing through a center of the second empty area formed in the plurality of eighth trenches.

11. The capacitor of claim 9, comprising:
a first support bar area corresponding to an area in which the first cell and the second cell are spaced apart from each other in the second direction;
a second support bar area corresponding to an area in which the first trench array and the third trench array, the second trench array and the fourth trench array, the fifth trench array and the seventh trench array, and the sixth trench array and the eighth trench array are spaced apart from each other;
a third support bar area corresponding to an area in which the first cell and the second cell are spaced apart from each other in the first direction;
a fourth support bar area corresponding to an area in which the first trench array and the second trench array, the third trench array and the fourth trench array, the fifth trench array and the sixth trench array, and the seventh trench array and the eighth trench array are spaced apart from each other; and
a fifth support bar area corresponding to the first empty area and the second empty area.

12. The capacitor of claim 11, further comprising a plurality of metal contacts formed at points at which a plurality of first virtual center lines intersect a plurality of second virtual center lines,
wherein the plurality of first virtual center lines pass through centers between the plurality of trenches disposed adjacent to each other and extend in an extending direction of each of the plurality of trenches in each of the first to eighth trench arrays,
the plurality of second virtual center lines pass through a center of each of the first to fifth support bar areas and extend in an extending direction of each of the first to fifth support bar areas, and
the plurality of metal contacts are formed in the first to fifth support bar areas along the plurality of second virtual center lines.
